(19) United States
(12) Patent Application Publication
(10) Pub. No.: US 2020/0410147 A1
(43) Pub. Date: Dec. 31, 2020

(54) Aerodynamic derivatives calculation method for flight vehicle

(71) Applicant: VIETTEL GROUP, Ha Noi City (VN)

(72) Inventors: QUANG DUC TRAN, Ha Noi City (VN); NGOC KHANH PHAM, Hoa Binh City (VN); TUAN ANH TRAN, Yen Dinh District (VN)

(73) Assignee: VIETTEL GROUP, Ha Noi City (VN)

(21) Appl. No.: 16/860,655

(22) Filed: Apr. 28, 2020

(30) Foreign Application Priority Data
Jun. 28, 2019 (VN) 1-2019-03459

(51) Int. Cl. G06F 30/28; G06F 30/15

(52) U.S. Cl. CPC G06F 30/28; B64C 30/00; G06F 30/15

(57) ABSTRACT

The invention proposes a method of calculating aerodynamic derivatives for flight vehicle including the following steps: step 1: simulation and calculation of static aerodynamic coefficients for flight vehicle; step 2: simulate forced harmonic oscillation, specifically: create the harmonic oscillation profile by channels and determine the combined derivative according to the pitch, roll and yaw channels for at least 3 different frequencies; step 3: calculate the aerodynamic derivatives for each channel, specifically: establish a mathematical model describing the forced harmonic oscillations according to the channels, developing an optimal program to minimize the cost function and estimate parameters.

### FIELD OF THE INVENTION

The invention is directed to an aerodynamic derivatives calculation method for high speed flight vehicle (transonic and supersonic). The invention can be applied in aeronautics.

### BACKGROUND DESCRIPTION

With increasing demands both civil and military, the field of Aerospace is growing. Along with that, many types of flying vehicles were born, including subsonic and supersonic flight vehicle. In addition, the increasingly strict requirements for the technical features of flying objects. One of them is to meet the requirements for complex maneuverability of a flying object.

In order to meet these features, it is necessary to build an accurate mathematical model for simulation process in the design cycle of the flight vehicle and its subsystems.

The aerodynamic derivative coefficients describe the ability of the flight vehicle to stabilize and react to aerodynamic disturbances acting during operation. Aerodynamic derivative coefficients play an important role in controlling flight vehicle to operate accurately and effectively.

In the past, aerodynamic derivative coefficients needed to be calculated using a wind tunnel (aerodynamic chamber) with high-precision sensors, which consumed a large cost of testing. Thanks to the development of simulation industry and especially in aerodynamic simulation, the authors developed a method to calculate aerodynamic stability derivatives to different control channels for flight vehicle.

Currently, there has not been any published document about the calculation of the aerodynamic derivatives for high-speed flight vehicle with high reliability.

### TECHNICAL BACKGROUND OF THE INVENTION

The purpose of the invention is to propose an aerodynamic derivatives calculation method for high speed flight vehicle (transonic and supersonic). The invention can be applied in aeronautics.

To achieve this purpose, the invention proposes a method of calculating aerodynamic derivative coefficients for flight vehicle including the following steps:

Step 1: Simulation and calculation of static aerodynamic coefficients for flight vehicle, as follows,

set up and prepare geometric models;

create computational domain and mesh;

set up solve, check and evaluate simulation models;

calculate static aerodynamic parameters;

Step 2: Simulate forced harmonic oscillation, specifically: create the harmonic oscillation profile by channels and determine the combined derivative according to the pitch, roll and yaw channels for at least 3 different frequencies;

step 3: calculate the aerodynamic derivatives for each channel, specifically: establish a mathematical model describing the forced harmonic oscillations according to the channels, developing an optimal program to minimize the cost function and estimate parameters.

The aerodynamic calculation method of the aerodynamic derivative coefficients for flight vehicle according to the invention in which the steps of meshing in step 1 are as follows:

general settings for meshing model: physical properties of simulation model, meshing parameters, boundary layer parameters, . . . ;

control mesh settings for faces, edges, boundary layer parameters, . . . ;

preview, check surface mesh, boundary layer and generate volumetric meshing;

evaluate grid quality according to the standards, analyze grid quality chart.

The aerodynamic calculation method of the aerodynamic derivative coefficients for flight vehicle according to the invention in which the steps to set up solver, check and evaluate the simulation model in step 1 are as follows:

select solver;

select turbulent model for fluid flow;

set up air properties;

set up boundary conditions;

set up calculation method.

### BRIEF DESCRIPTION OF THE DRAWINGS

FIG. 1: Diagram describes the process of calculation method belong to the invention.

FIG. 2: Flowchart shows the steps to perform fluid dynamic simulation.

FIG. 3: Face, inflation and volume grid of computational domain

FIG. 4: Diagram of orthogonal quality

FIG. 5: Diagram of skewness quality.

### DETAILED DESCRIPTION OF THE INVENTION

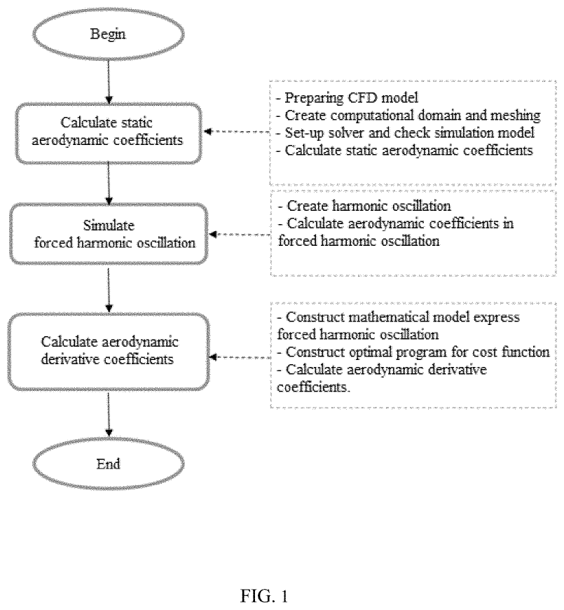

Refer to FIG. 1, the invention proposes a method to calculate aerodynamic derivative coefficients for flight vehicle including the following steps:

Step 1: Simulation and Calculation of Static Aerodynamic Coefficients for Flight Vehicle

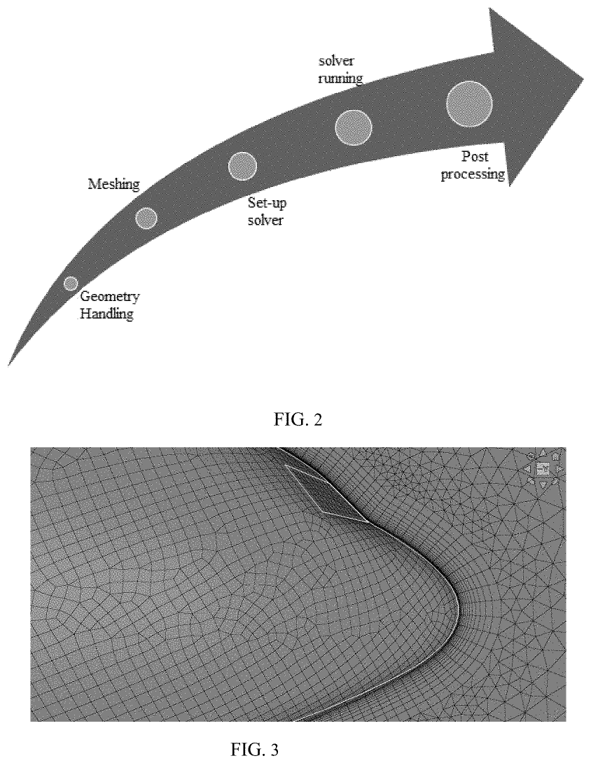

Refer to FIG. 2, diagram describes the process performing the calculation of static aerodynamic coefficients of flight vehicle including:

a) Geometry handling.

Using computer-aided design software to build 3D model of flight vehicle, then export.the CAD file to .xt, .stp or .igs format, etc. to import to geometry modul Ansys DesignModeler—an application in the Ansys Workbench designed to be used as a repair and prepare tool for geometric model.

3D CAD model not only must ensure the requirements to describe all the aerodynamic characteristics of the flight vehicle, but also need to be simplified, appropriate for fluid dynamic simulation.

Geometry handling includes: repair and simplify geometric model. In addition, the model should be adjusted to the stability coordinate system, the origin of the coordinates coincide with the center of gravity of the flight vehicle.

b) Create computational domain and meshing.

After geometry handling, proceed to create a computational domain for the fluid domain. The computational domain must ensure that the results of the calculation area around the object are not affected by the boundary conditions. The minimum size of the computational domain must ensure the following condition: the nearest distance in must be at least 10 times the characteristic length of the object.

Calculation of aerodynamic parameters of flying objects using simulation software, is built based on finite volume method to solve the continuity equation and conservation equations in the computational domain. Therefore, the computational domain must be divided into small elements to solve these equations on each element. Grid quality significantly affects simulation results. The finer the grid (small grid size) lead to the more accurate results for the change of quantities and describe more precisely the geometry of the calculated object.

The system can be meshed with specialized software (Gambit, ICEM CFD or ANSYS Meshing). However, for flight vehicles with complex geometry, meshing in Gambit or ICEM CFD is very complicated, time-consuming and labor-intensive and difficult to achieve high meshing quality.

ANSYS Meshing is a module in ANSYS Workbench specializing in meshing for different types of problems: structural, collision, external flow, internal flow, etc. Using ANSYS Meshing \generates meshing models without spending too much time, but can give accurate results compared to meshing by other methods if good meshing (the difference is less than 1%).

The steps of meshing are performed on Ansys Meshing as follows:
General settings for meshing model: physical properties of model, meshing parameters, boundary layer parameters, . . . .

For different simulation problems, the physical properties of the problem are also different, which requires the meshing of the computational domain to be different to describe the physical nature of the object. Calculating the aerodynamic derivatives of flight vehicle, actually is to simulate the external flow of air impacting the flight vehicle. Therefore the choice of physical requirements for meshing would be chosen as an external aerodynamic simulation.

The global meshing parameters for the entire computational domain should be set based on the sizes of the object and the domain. Size of smallest and largest grid element, meshing method according to curvature capturing, proximity capturing, . . . are set for the entire domain based on the analysis of the geometry of the object.

The boundary layer parameters are calculated based on the maneuver condition of flight vehicle, the characteristic size, the airflow properties, etc.

The table below is an example that sets global parameters for the meshing model.

TABLE 1
Meshing parameter settings in ANSYS Meshing

| | |
|---|---|
| Element Order | Linear |
| Element Size | 0.5 m |
| Export Format | Standard |
| Export Preview Surface Mesh | No |
| Sizing | |
| Use Adaptive Sizing | No |
| Growth Rate | Default (1, 2) |
| Max Size | 1.0 m |
| Mesh Defeaturing | Yes |
| Defeature Size | 5.e−004 m |

TABLE 2
Inflation settings
Inflation

| | |
|---|---|
| Automatic Inflation | No |
| Inflation Option | First Layer Thickness |
| First Layer Height | 1.2e−005 m |
| Maximum Layers | 20 |
| Growth Rate | 1.15 |
| Inflation Algorithm | Pre |
| View Advanced Options | No |

Control the meshing settings for specific faces, edges, boundary layer parameters

For flight vehicles in general, including wing-body, stabilizers, control surfaces, . . . dimension ratio between these parts is different (the body is much larger than the wing), however, aerodynamic characteristics are mainly shown in the wings of the object. Therefore, the need is to provide mesh grid sizes in these areas that are very small in order to capture the phenomena of flow when passing these parts of a flight vehicle.
Preview, check surface mesh, boundary layer and generate volume mesh

After setting up the global and local meshing parameters. Generate surface mesh check surface mesh quality. Perform in ANSYS Meshing with the command “Check the surface mesh”. On the surfaces of the object showing the surface mesh, the user can analyze the geometric capturing of the grid cells, the quality of capture to important geometric details to adjust the meshing parameters in the previous step to reach desired quality.

After checking the surface mesh, generate volume mesh by executing “Generate volume mesh” command.
Check mesh quality according to standards, analyze grid quality chart:

After the generate volume mesh step, it is necessary to check the standards to be met for the generated mesh of the computational domain. In ANSYS Meshing software, perform checking according to each standard in the “Quality” section and select type of quality in the “Mesh Metric” section. For the aerodynamic simulation problem of the external flow of transonic flight vehicle, the quality criteria that should be considered is: orthogonal quality of elements, skewness, aspect ratio. Details:
Orthogonal quality is shown on the table below. The best quality is when the orthogonal quality reaches the value of 1. Mesh quality is satisfactory when the orthogonal quality is from 0.15 and above.

TABLE 3
Orthogonal quality.

| Unacceptable | Bad | Acceptable | Good | Very good | Excellent |
|---|---|---|---|---|---|
| 0-0.001 | 0.001-0.14 | 0.15-0.20 | 0.20-0.69 | 0.70-0.95 | 0.95-1.00 |

The best skewness quality is equal zero represents the equilateral element (for the surface mesh is an equilateral triangle, the volume mesh is equilateral tetrahedra). Mesh quality is acceptable when the skewness quality is less than 0.94. The specific table of evaluating the mesh quality of the computational domain is as follows:

TABLE 4
Skewness quality

| Unacceptable | Bad | Acceptable | Good | Very good | Excellent |
|---|---|---|---|---|---|
| 0.98-1.00 | 0.95-0.97 | 0.80-0.94 | 0.50-0.80 | 0.25-0.50 | 0-0.25 |

The aspect ratio shows ratio between the radius of the excircle and the incircle of mesh elements. The aspect ratio of the mesh is satisfactory when it is less than 1000.

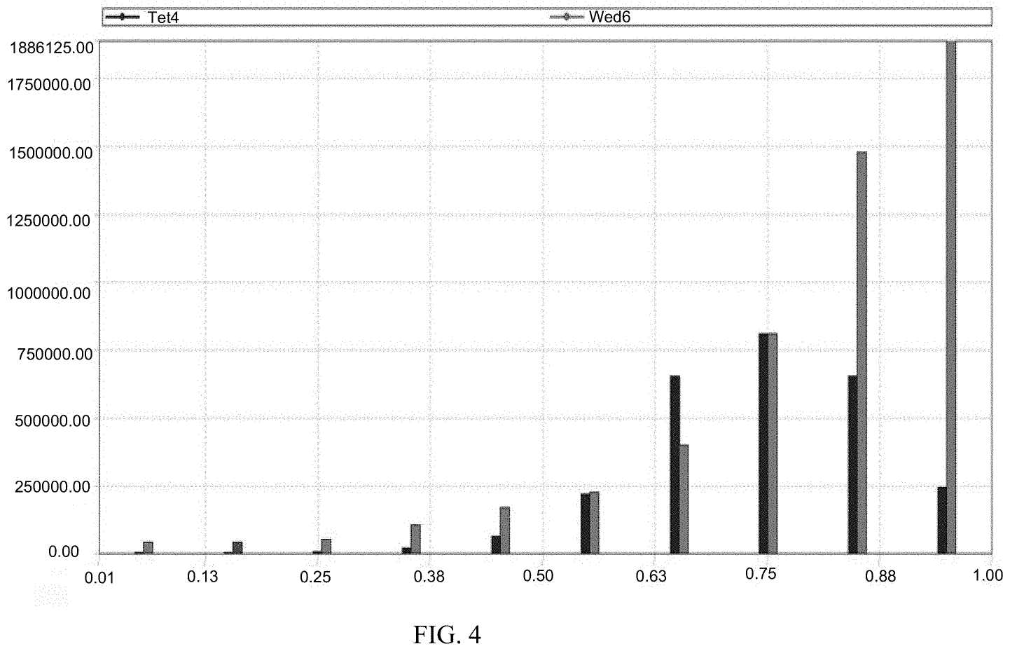

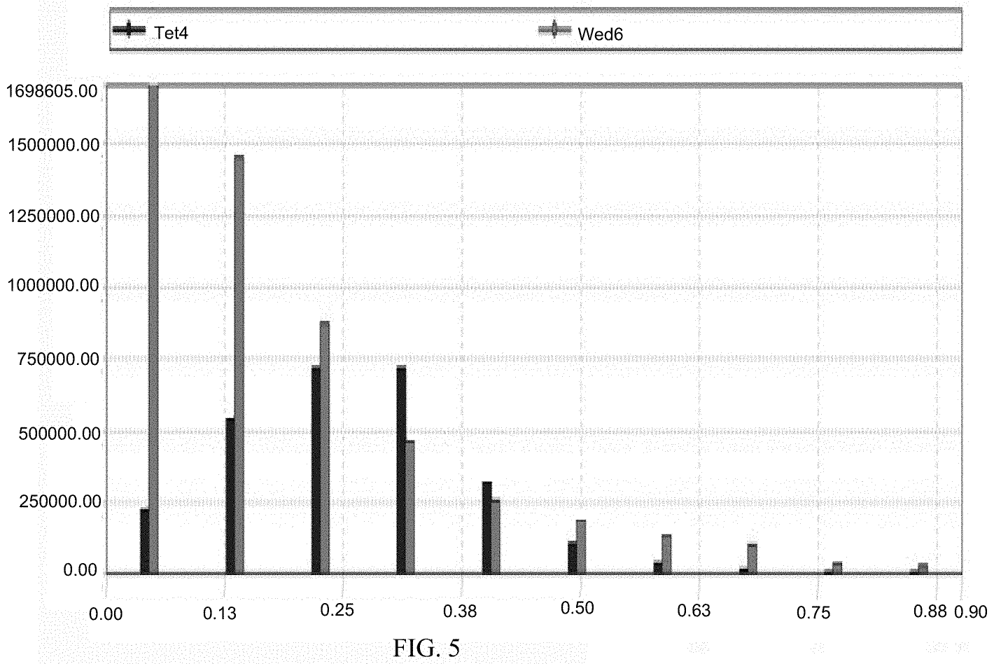

In addition, when selecting in the “Mesh quality”, ANSYS Meshing software also shows the specific chart of distribution of element quality as show in FIG. 4 and FIG. 5. Based on that, the element can be clearly checked. In any area of bad quality or unsatisfactory, it is necessary to adjust the global and local meshing parameters.

c) Set up solver, check and evaluate simulation models.

Use ANSYS Fluent software to simulate the aerodynamic characteristics of flight vehicle. This is one of the strongest modules in fluid dynamic simulation. The verification results of the program have been confirmed through many scientific papers, used in the field of Aerospace of many large companies in the world. The reliability of the results is proved based on the small difference between simulation and experimental results.

ANSYS Fluent provides comprehensive modeling solutions for various fluid problems such as compressible and imcompressible flow, laminar and turbulence flow. Alternatively, steady-state (time-independent) or unsteady (time-dependent) analyzes can be performed, providing the ability to generally assess aerodynamic phenomena that occur in operation of flight vehicle.

Steps to perform aerodynamic simulation and calculation using ANSYS Fluent software are as follows:
Select a solver:

Flow characteristics (compressible or non-compressible) are characterized by the Mach number (ratio of flight vehicle's speed and sound speed). For high-speed flight vehicle (transonic and supersonic), the flow is compressible, so the solver type that needs to be selected is Density-based.

In the aerodynamic simulation, depending on the nature of the problem, one can set up the solver to be unsteady or steady. In this step, calculate the static aerodynamic coefficients, so the selected solver is steady.
Select turbulent model

In engineering applications, the correct calculation of turbulence is absolutely unnecessary. Disturbances can be modeled so that we can generally understand the effects of the disturbances on the research object. In the aerodynamic simulation of high-speed flight vehicle, the method used to modeling the turbulent flow is calculation averaged Navier-Stokes equations over time, using the k-ω SST model. This turbulence model uses the equation of the specific dissipation ω. The set-up required to provide input parameters includes constants in the turbulence model equation: Alpha * _inf, Alpha_inf, Beta * _inf, Zeta *:
Set airflow properties

For high speed flight vehicle, the nature of the air is now considered as the ideal gas. The settings for ideal gases include: density, heat transfer coefficient, viscosity, specific heat capacity, . . . . The following provides an example of the setting up of properties for airflow.
Desity (density): ideal gas
Cp: specific heat capacity of airflow
Thermal Conductivity: heat transfer coefficient of airflow
Viscosity: viscosity of airflow
Reference Viscosity: reference viscosity of airflow
Reference Temperature: The reference temperature of airflow
Effective Temperature: Effective temperature of airflow
Setting boundary conditions:

For the entire computational domain, it is necessary to set up boundary conditions for the simulation model. It is necessary to determine: the type of boundary conditions (object, symmetry region, input zone, output zone, . . . ), the location of the boundary condition, the physical model of the boundary condition.

For the aerodynamic simulation model of a flight vehicle, the boundary conditions are applied as follows:
Inlet: atmospheric pressure and velocity of flight vehicle
Output: outlet atmospheric pressure
Object: the entire object (the velocity on wall is zero)
The example for setting up the input condition is as follows:
Gauge pressure: Gauge pressure of airflow
Mach Number: Mach number of airflow (ratio of flight vehicle's speed and sound speed).
X, Y, Z-Component of Flow Direction: direction vector of flow velocity
Turbulent Intensity, Turbulent Viscosity Ratio: turbulence properties of fluid
Set up calculation method

Set up a discretization method for convection conditions for each equation of the Navier-Stokes equations. The conservation equations of the flow is set up to second order.

d) Calculation of static aerodynamic coefficients.

After steps in c), execute the solver on the Ansys Fluent software. The results obtained after the computational solver executing is completely shown in the form of matrices of calculated variables (pressure, velocity, temperature, etc.). In addition, the static aerodynamic coefficients of the flight vehicle 03 force and 03 moment coefficients will be exported directly from the software. Summary of results can be presented in the form of the following table:

Results of Calculation of Force and Aerodynamic Moment

| Angle of | | | | | | |
|---|---|---|---|---|---|---|
| Attack | Fx | Fy | Fz ] | Mx | My | Mz |
| [°] | [N] | [N] | [N | [Nm] | [Nm] | [Nm] |
| −2 | | | | | | |
| 0 | | | | | | |
| 2 | | | | | | |

The results obtained will be presented in the form of non-dimension coefficients to facilitate processing and calculation.

In addition to analyzing the results in the form of data, the results can also be presented in the form of pressure contour, temperature contour, streamlines, . . . in order to make a preliminary assessment of the aerodynamic characteristics of the airflow in the computational domain.

Step 2: Simulate Forced Harmonic Oscillation

A flight vehicle oscillates around the Y axis (pitching axis) with angular frequency ω with a small amplitude. Assuming that the flight vehicle is absolutely hard and the sinusoidal forced oscillation is described by the following formula:

$$\{ \begin{matrix}θ = {θ}_{0} sin ( ω t ) \\ \dot{θ} = ω {θ}_{0} cos ( ω t ) = {ω}_{y} \\ \ddot{θ} = - {ω}^{2} {θ}_{0} sin ( ω t ) = {\dot{ω}}_{y} \\ Δ α = θ = {θ}_{0} sin ( ω t ) \\ Δ \dot{α} = \dot{θ} = ω {θ}_{0} cos ( ω t )\end{matrix} \qquad ( 1 )$$

Where:

θ—Pitch angle; ω_{y}—angular velocity around Oy;

α—angle of attack; ω—frequency

Setting up the oscillation for flight vehicle follows the oscillation law written in the “C” programming language and hook in the simulation software as a “User-defined function”.

The time-dependent pitching moment of flight vehicle is expressed by the Taylor expansion as follows:

$${M}_{y} = {M}_{y 0} + {M}_{y}^{α} Δ α + {M}_{y}^{\dot{α}} Δ \dot{α} + {M}_{y}^{{ω}_{y}} {ω}_{y} + {M}_{y}^{{\dot{ω}}_{y}} {\dot{ω}}_{y} + \hat{Δ} ( Δα , {ω}_{y} ) \qquad ( 2 )$$

Where:

M_{y0}—pitching moment at trim condition

M_{y}^{α}, M_{y}^{\dot{α}}, M_{y}^{ω}^{_{y}}, M_{y}^{\dot{ω}}^{_{y}}—pitching moment derivatives for angle of attack α,

first—order derivative \dot{α}, angular velocity ω_{y}, first—order derivative \dot{ω}_{y}

\hat{Δ}—high—order derivatives.

Combined with equations (1) and (2) and ignoring the high-order derivatives, pitching moment of a flight vehicle is simply reduced to:

$${M}_{y} = {M}_{y 0} + ( {M}_{y}^{α} - {ω}^{2} {M}_{y}^{{\dot{ω}}_{y}} ) {θ}_{0} sin ( ω t ) + ( {M}_{y}^{\dot{α}} + {M}_{y}^{{ω}_{y}} ) {ω}_{y} {θ}_{0} cos ( ωt ) \qquad ( 3 )$$

As ωt=2 nπ, equation (3) can be written as:

$$\begin{matrix}( {M}_{y}^{\dot{α}} + {M}_{y}^{{ω}_{y}} ) = \frac{{M}_{y ω t = 2 n π} - {M}_{y 0}}{ω {θ}_{0}}\end{matrix} \qquad ( 4 )$$

Use reduced frequency k=ωl/2V, (V_{*}—velocity of vehicle, l—reference length) to express equation (4) as non-dimension form, the final formula for calculating the combined derivative by the small amplitude oscillation method is:

$$\begin{matrix}{C}_{m \dot{α}} + {C}_{mq} = \frac{{C}_{My ω t = 2 n π} - {C}_{my 0}}{k {θ}_{0}}\end{matrix} \qquad ( 5 )$$

Where C_{m\dot{α}} vá C_{mq} are pitching aerodynamic derivatives which will be calculated. In this step, eq. (5) allows the calculation of the combined derivative of the pitching aerodynamic derivatives for each angular frequency ω. The result of calculating the pitching combined derivative will be calculated for at least 3 different angular frequencies to use in the next step to separately calculate each aerodynamic derivative coefficients.

The combined derivatives of yaw and roll are similar.

### Step 3: Calculate Dynamic Derivative Derivatives Per Channel.

To calculate components of combined derivative (for example, in pitch is C_{m\dot{α}} vá C_{mq}), compare the moment between the harmonic oscillator mathematical model and simulation results using ANSYS Fluent software.

Pitching moment of a flight vehicle oscillating around Oy axis is shown by the following formula:

$${m}_{y} = {m}_{{y}_{0}} + {m}_{y}^{α} α + Δ {m}_{{y}_{rot}} + Δ {{m}_{y}}_{dyn} \qquad ( 6 )$$

Where:

m_{y}_{₀}—static pitching moment

$$Δ {m}_{{y}_{rot}} , Δ {m}_{{y}_{dyn}}$$

component generated due to rotation and translation.

The change of rotation pitching moment

$$Δ {m}_{{y}_{rot}}$$

due to angular velocity ω_{y}:

$$Δ {m}_{{y}_{rot}} = {m}_{y}^{{\overline{ω}}_{y}} {\overline{ω}}_{y} + {m}_{y}^{{\overline{\dot{ω}}}_{y}} {\overline{\dot{ω}}}_{y} \qquad ( 7 )$$

Where:

m_{y}^{ω̅}^{_{y}}, m_{y}^{\dot{ω̅}}^{_{y}} depending on angle of attack α

$${\overline{ω}}_{y} = \frac{{ω}_{y} l}{2 V}$$

non-dimension angular velocity

l—reference length, V—flight velocity

Dynamic moment component

$$Δ {m}_{{y}_{dyn}}$$

satisfies the following first order differential equation:

$${T}_{r} Δ {\dot{m}}_{{y}_{rot}} + Δ {m}_{{y}_{dyn}} = {a}_{r} {T}_{r} \dot{α} \qquad ( 8 )$$

Where: Tᵣ—time constant, αᵣ—dynamic coefficient.

Assuming the flight vehicle perform a forced oscillation with frequency f angular frequency ω_{f}=2πf, and reduced frequency

$${\overline{ω}}_{f} = \frac{{ω}_{f} l}{2 V} .$$

Angle of attack in forced oscillation with amplitude α_{A} as follow:

α=α₀+ₐsinωt (9)

First order derivative of angle of attack:

\dot{α}=α_{A}ΩcosΩt (10)

Eq. (4) become:

$$( 11 )$$

$$\begin{matrix}{m}_{y} = {m}_{{y}_{0}} + ( {m}_{y}^{α} - {\overline{ω}}^{2} {m}_{y}^{\overline{{\dot{ω}}_{y}}} ) {α}_{A} sin ω t + ( {m}_{y}^{\overline{{ω}_{y}}} + {m}_{y}^{\overline{\dot{α}}} ) {α}_{A} ω cos ω t + Δ {m}_{{y}_{\overline{d} \hat{{o}_{.}} ng}}\end{matrix} \qquad$$

Combined with dynamic component, pitching moment of mathematical model will take the form:

$$\begin{matrix}{m}_{yMAT} = [ ( {m}_{{y}_{t \tilde{i} nh}}^{α} + \frac{{a}_{p} \cdot {T}_{p}^{2} {\overline{ω}}^{2}}{1 + {T}_{p}^{2} {\overline{ω}}^{2}} ) \cdot sin α ] \cdot {α}_{A} \cdot sin ω + \\ [ ( {m}_{y}^{q} + \frac{{a}_{p} \cdot {T}_{p}}{1 + {T}_{p}^{2} {\overline{ω}}^{2}} ) \cdot cos α ] \cdot {α}_{A} \cdot ω \cdot sin ω\end{matrix} \qquad ( 12 )$$

On the other hand, Taylor's expansion of harmonic oscillation for moment is given by the following formula:

$$Δ {m}_{y} = [ ( {m}_{{y}_{st}}^{α} - {\overline{ω}}^{2} \cdot {m}_{y}^{\dot{q}} ) ] \cdot {α}_{A} \cdot sin ω + [ ( {m}_{y}^{q} + {m}_{y}^{\dot{α}} ) ] \cdot {α}_{A} \cdot ω \cdot sin ω \qquad ( 13 )$$

Combining equations (12) and (13):

$$\begin{matrix}\begin{matrix}[ ( {m}_{{y}_{st}}^{α} + \frac{{a}_{p} \cdot {T}_{p}^{2} {\overline{ω}}^{2}}{1 + {T}_{p}^{2} {\overline{ω}}^{2}} ) \cdot sin α ] = ( {m}_{{y}_{st}}^{α} - {\overline{ω}}^{2} \cdot {m}_{y}^{\dot{q}} ) \\ [ ( {m}_{y}^{q} + \frac{{a}_{p} \cdot {T}_{p}}{1 + {T}_{p}^{2} {\overline{ω}}^{2}} ) \cdot cos α ] = ( {m}_{y}^{q} + {m}_{y}^{\dot{α}} )\end{matrix} & ( 14 )\end{matrix}$$

To calculate the dynamic derivative coefficients, construct a cost function that express the difference between mathematical model and physical model as follow:

$$J = {\{ [ ( {m}_{y}^{q} + {m}_{y}^{\dot{α}} ) - {m}_{y}^{q} ] ( 1 + {T}_{p}^{2} {\overline{ω}}^{2} ) - ( {a}_{p} \cdot {T}_{p} ) \cdot cos α \}}^{2} \qquad ( 15 )$$

Tₚ, (aₚ. Tₚ) and m_{y}^{q}(or cm_{q}) are parameters of cost function. The value of the cost function J is calculated on at least 3 angular frequency in step 2. Use the extremes find methods to find the minimum value of the function J. The value of the variables that make the smallest J function will be a optimal solution making the smallest difference between simulation model and mathematical model. One of those coefficients is the pitching moment coefficients in angular velocity cm_{q}. Combined with the Eq. (5), we will find the remaining component of the dynamic derivative coefficients—the pitching moment of according to the rate of change of angle of attack (cmad).

The method is applied to the same calculation for roll and yaw.

1. Methods of calculating aerodynamic derivatives for a flight vehicle comprising the following steps:
Step 1: Simulation and calculation of static aerodynamic coefficients for the flight vehicle, as follows,
set up and prepare geometric models;
create a computational domain and mesh;
set up solve, check and evaluate simulation models;
calculate static aerodynamic parameters;
Step 2: Simulate forced harmonic oscillation, specifically: create a harmonic oscillation profile by channels and determine a combined derivative according to a pitch, a roll and a yaw channels for at least 3 different frequencies;
step 3: calculate aerodynamic derivatives for each channel, specifically: establish a mathematical model describing the forced harmonic oscillations according to the channels, developing an optimal program to minimize a cost function and estimate parameters.

2. The method of calculating aerodynamic derivatives for a flight vehicle according to claim 1 in which the steps of meshing at step 1 are as follows:
general settings for the meshing model: physical properties of the simulation model are external flow simulation; meshing parameters for the entire computational domain should be set based on a size of the flight vehicle, a size of the computational domain, a smallest and largest cell size, a meshing method by the curvature or proximity capture is established for the entire computational domain based on an analysis of the geometry of flight vehicle; boundary layer parameters are calculated based on a maneuver condition of the flight vehicle, the characteristic size, gas properties, . . . ;
control mesh settings for faces, edges, boundary layer parameters, and so on; meshing in these areas is particularly smaller to capture the phenomena of flow when passing these parts;
preview, check surface mesh, boundary layer and generate volume mesh;
check grid quality according to standards, mesh quality chart analysis, best orthogonal quality when an orthogonal quality reaches the value of 1, a mesh quality is satisfactory when the orthogonal quality is 0, 15 and above; a best skewness is equal to zero represents an ideal element (for the surface mesh is equilateral triangle, with the volume mesh being equilateral tetrahedra), the mesh quality is acceptable when skewness is less than 0.94; an aspect ratio shows ratio between a radius of an excircle and an incircle of mesh elements, an aspect ratio of the mesh is satisfactory when it is less than 1000.

3. The method of calculating aerodynamic derivatives for flight vehicle according to claim 1 in which the steps to set up the solver, check and evaluate the simulation models in step 1 are performed:
select a solver; chosen solver type is density-based, a time option is steady;
select a turbulent model;
set airflow properties; a properties set for an ideal gas include: density, heat transfer coefficient, viscosity, specific heat capacity;
set boundary conditions, including: inlet: atmospheric pressure and velocity of flight vehicle; outlet: outlet atmospheric pressure; wall: the entire flight vehicle (the velocity at wall is equal zero);
set up calculation method, specifically setting up discretization method for convection conditions of the Navier-Stokes equations, conserving equations, kinetic energy and specific dissipation rate choose second order.
